(19) United States
(12) Patent Application Publication
(10) Pub. No.: US 2025/0264515 A1
(43) Pub. Date: Aug. 21, 2025

(54) CATV SYSTEM SIGNAL LEAKAGE DETECTION USING A DRONE

(71) Applicant: Charter Communications Operating, LLC, St. Louis, MO (US)

(72) Inventor: Patrick Phillip Hunter, Saint Charles, MO (US)

(21) Appl. No.: 18/582,164

(22) Filed: Feb. 20, 2024

(51) Int. Cl. G01R 31/08; G05D 1/689; G05D 109/20; H04N 17/00

(52) U.S. Cl. CPC G01R 31/083; G05D 1/689; G05D 2109/20; H04N 17/004

(57) ABSTRACT

A computing system comprising a drone detects a signal leakage in an above-ground cabling infrastructure. The computing system determines that a cable system component of the above-ground cabling infrastructure is a source of the signal leakage based at least in part on an amplitude of the signal leakage. The computing system sends, to a destination device, a notification that identifies the cable system component.

### BACKGROUND

Cable television (CATV) systems are required to operate as closed systems without signals emitting from the system or signals entering from external sources. CATV system signal leakage detection allows cable system operators to ensure that the CATV system meets these signal leakage requirements.

### SUMMARY

The examples disclosed herein perform CATV system signal leakage detection using drones. Traditional CATV system signal leakage detection is time consuming, costly, and unsafe due to technicians climbing to a location in an above-ground cabling infrastructure to find and measure signal leakage. A drone configured to detect signal leakage in a CATV system can instead be used to determine the source of the signal leak, thereby decreasing the time to find the source of the signal leak and increasing technician safety.

In one example, a method for CATV system signal leakage detection using drones is provided. The method includes detecting, by a computing system comprising a drone, a signal leakage in an above-ground cabling infrastructure. The method further includes determining, by the computing system, that a cable system component of the above-ground cabling infrastructure is a source of the signal leakage based at least in part on an amplitude of the signal leakage. The method further includes sending, by the computing system to a destination device, a notification that identifies the cable system component.

In another example, a computing device for CATV system signal leakage detection using drones is provided. The computing device includes a memory and a processor device coupled to the memory. The processor device is to detect a signal leakage in an above-ground cabling infrastructure. The processor device is further to determine that a cable system component of the above-ground cabling infrastructure is a source of the signal leakage based at least in part on an amplitude of the signal leakage. The processor device is further to send, to a destination device, a notification that identifies the cable system component.

In another example, a non-transitory computer-readable storage medium for CATV system signal leakage detection using drones is provided. The non-transitory computer-readable storage medium includes computer-executable instructions to cause a processor device to detect a signal leakage in an above-ground cabling infrastructure. The instructions further cause the processor device to determine that a cable system component of the above-ground cabling infrastructure is a source of the signal leakage based at least in part on an amplitude of the signal leakage. The instructions further cause the processor device to send, to a destination device, a notification that identifies the cable system component.

Individuals will appreciate the scope of the disclosure and realize additional aspects thereof after reading the following detailed description of the examples in association with the accompanying drawing figures.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1 is a block diagram of a computing system in which examples of CATV system signal leakage detection using drones may be practiced;

FIG. 2 is a flowchart illustrating operations performed by the computing device of FIG. 1 for CATV system signal leakage detection using drones, according to one example;

FIG. 3 is a block diagram of the computing system of FIG. 1 for CATV system signal leakage detection using drones, according to one example;

FIG. 4 is a block diagram of the computing system of FIG. 1 for CATV system signal leakage detection using drones, according to one example;

FIG. 5 is a block diagram of a computing device suitable for implementing examples, according to one example.

### DETAILED DESCRIPTION

The examples set forth below represent the information to enable individuals to practice the examples and illustrate the best mode of practicing the examples. Upon reading the following description in light of the accompanying drawing figures, individuals will understand the concepts of the disclosure and will recognize applications of these concepts not particularly addressed herein. It should be understood that these concepts and applications fall within the scope of the disclosure and the accompanying claims.

Any flowcharts discussed herein are necessarily discussed in some sequence for purposes of illustration, but unless otherwise explicitly indicated, the examples are not limited to any particular sequence of steps. The use herein of ordinals in conjunction with an element is solely for distinguishing what might otherwise be similar or identical labels, such as “first message” and “second message,” and does not imply an initial occurrence, a quantity, a priority, a type, an importance, or other attribute, unless otherwise stated herein. The term “about” used herein in conjunction with a numeric value means any value that is within a range of ten percent greater than or ten percent less than the numeric value. As used herein and in the claims, the articles “a” and “an” in reference to an element refers to “one or more” of the elements unless otherwise explicitly specified. The word “or” as used herein and in the claims is inclusive unless contextually impossible. As an example, the recitation of A or B means A, or B, or both A and B. The word “data” may be used herein in the singular or plural depending on the context.

Cable television (CATV) systems are required to operate as closed systems without signals emitting from the system (i.e., egress) or signals entering from external sources (i.e., ingress). CATV system signal leakage detection allows cable system operators to ensure that the CATV system meets these signal leakage requirements. CATV system signal leakage can be the result of loose or damaged components of a CATV system, and the radio frequencies (RF) used by CATV systems can interact with other RF signals in the air. As a result, Federal regulations require CATV systems to maintain a low amount of CATV system RF signal leakage. For instance, CFR Title 47, Part 76, Subpart K-Technical Standards defines that when operating in the 108-137 MHz and 225-400 MHz frequency bands, which is where common cable TV transmissions may be coincident with other over-the-air frequencies such as frequencies related to air traffic control and aeronautical navigation, RF signal leakage (i.e., egress) can be no more than 20 μV/m (microvolts per meter) when measured at 3 meters (47 CFR § 76.610, 47 CFR § 76.611).

Many different components of a CATV system may contribute to signal leakage that exceeds these required levels, such as active components, passive components, and coaxial cable. Several methods can be used to determine the source of the CATV system signal leakage, including flyovers in airplanes, drive-outs in cable company vehicles, and manual detection by a technician with handheld signal leakage equipment looking for a leaking cable signal. However, the final step in locating the source of the CATV system signal leakage is for a technician to manually detect the signal leakage with handheld signal leakage equipment, which can be dangerous when the signal leakage is from a component of an aerial cable plant. This traditional CATV system signal leakage detection is time consuming, costly, and unsafe due to technicians climbing to a location in an above-ground cabling infrastructure to find and measure signal leakage.

The examples disclosed herein perform CATV system signal leakage detection using drones. A drone configured to detect signal leakage in a CATV system can instead be used to determine the source of the signal leak, thereby decreasing the time to find the source of the signal leak and increasing technician safety. For instance, the drone can be equipped with an on-board signal leakage detector or be programmed to detect signal leakage, and use triangulation as a method to determine the cable system component that is the source of the signal leak when moving around the components of the CATV system.

A computing system that includes the drone can detect signal leakage in a CATV system, such as an above-ground cabling infrastructure, and determine the component of the CATV system that is the source of the signal leakage, such as based on the amplitude of the leaking signal and by using triangulation. Once the source of the signal leakage is identified, a notification can be sent to a device, such as a display device used by a technician, indicating the source of the signal leakage, and an image of the leaking component can be captured by the drone and stored in a database.

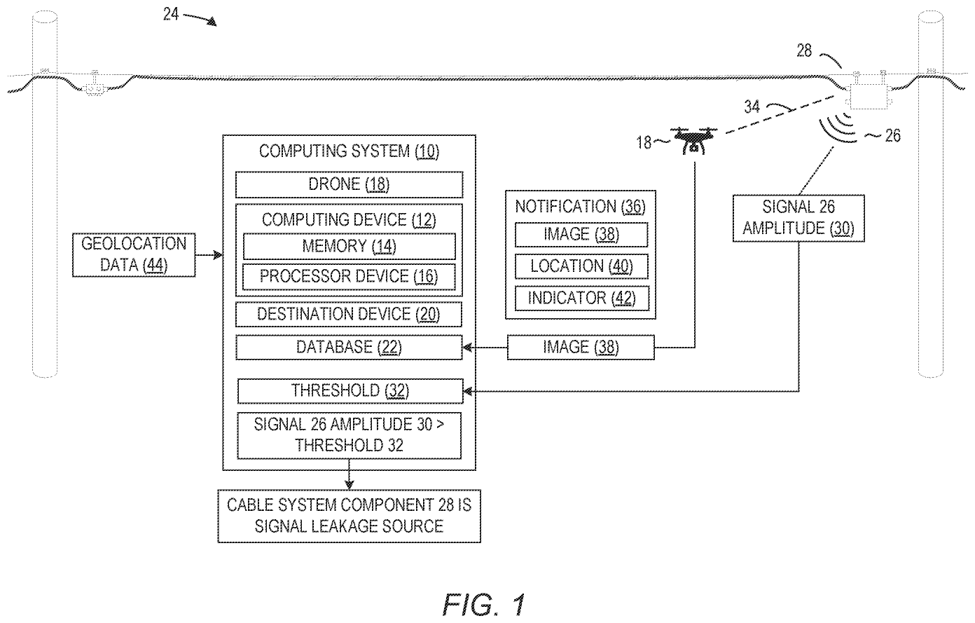

FIG. 1 is a block diagram of a computing system 10 in which examples of CATV system signal leakage detection using drones may be practiced. The computing system 10 includes a computing device 12 comprising a system memory 14 and a processor device 16. Although only the computing device 12 is illustrated with a system memory 14 and a processor device 16, any component of the computing system 10 may include one or more system memories and/or one or more processor devices. The computing system 10 may also include a drone 18 comprising a system memory and a processor device, a destination device 20 comprising a system memory and a processor device, and a database 22. For instance, the destination device 20 may be a display device that is configured to control the drone (e.g., a tablet computer, laptop, or mobile phone) and that can be used by a technician. In some implementations, the computing system 10 may include a plurality of drones, destination devices, and/or databases. It is to be understood that the computing system 10 in some examples may include constituent elements in addition to those illustrated in FIG. 1. It is further noted that while the computing device 12, the drone 18, the destination device 20, and the database 22 are shown as separate components, in other implementations, the computing device 12, the drone 18, the destination device 20, and the database 22 could be implemented in a single component or could be implemented in a greater number of components than four. In examples where the computing system 10 includes a plurality of drones, the functionality implemented by the drone 18 may be attributed to each drone of the plurality of drones. In examples where the computing device 12 comprises software instructions that program the processor device 16 to carry out functionality discussed herein, functionality implemented by the computing device 12 may be attributed herein to the processor device 16.

In the example of FIG. 1, the computing system 10 may detect a signal leakage in an above-ground cabling infrastructure 24 of a CATV system (e.g., an aerial cable plant). CATV system signal leakage may emanate from a loose or damaged component of the CATV system and may take the form of one or more conical shapes spreading as the signal propagates through free space. For example, the above-ground cabling infrastructure 24 may include utility poles that connect coaxial cables, splitters, cable signal amplifiers, cable taps, lashing wire, and other cabling infrastructure components together above ground. The signal leakage may be a leak of a signal 26, such as a radio frequency (RF) signal, from a cable system component 28 of the above-ground cabling infrastructure 24. For instance, the cable system component 28 may be a cable signal amplifier, a coaxial cable tap, or a coaxial cable, as non-limiting examples. The computing system 10, such as via the drone 18, can identify a signal that is produced by the above-ground cabling infrastructure 24 (e.g., signal 26) and that matches a predetermined type of signal in order to detect the signal leakage in the above-ground cabling infrastructure 24. For example, tags (e.g., a unique RF signal) can be used by a cable company to tag and then identify which signals that are propagating through free space or the air belong to cable system components owned by the cable company, and the computing system 10 can determine that the signal produced by the above-ground cabling infrastructure 24 (e.g., signal 26) has a tag that identifies the signal as coming from a cable system component of the cable company.

In some implementations, the computing system 10 can obtain geolocation data 44 (e.g., latitude and longitude coordinates and height data) that corresponds to a location of the above-ground cabling infrastructure 24 and cause the drone 18 to move to a location proximate to the above-ground cabling infrastructure 24 based on the geolocation data 44. Then, the computing system 10 can detect the signal leakage in the above-ground cabling infrastructure 24 once the drone 18 moves to the location proximate to the above-ground cabling infrastructure 24. For instance, the geolocation data 44 may be obtained from a database or central computing system utilized by the cable system operator of the above-ground cabling infrastructure 24. Additionally, the drone 18 can use a proximity algorithm to determine the location proximate to the above-ground cabling infrastructure 24 based on the geolocation data 44. For example, the geolocation data 44 may provide latitude and longitude coordinates and height data for the above-ground cabling infrastructure 24 and the proximity algorithm may instruct the drone 18 to move to a location two feet from the above-ground cabling infrastructure 24 based on the latitude and longitude coordinates and height data.

The computing system 10 may determine that the cable system component 28 of the above-ground cabling infrastructure 24 is a source of the signal 26 leakage based at least in part on an amplitude 30 of the signal 26 emitting from the cable system component 28. For example, the computing system 10 may cause the drone 18 to move to one or more locations that are in proximity to the cable system component 28 of the above-ground cabling infrastructure 24 such that the signal 26 can be detected, monitor the signal 26 emitting from the cable system component 28, and determine that the amplitude 30 of the signal 26 exceeds a predetermined threshold 32, such as the 108-137 MHz and 225-400 MHz frequency bands for cable TV transmissions where RF signal leakage (i.e., egress) can be no more than 20 μV/m (i.e., the amplitude 30) when measured at 3 meters from the cable system component 28 (47 CFR § 76.610, 47 CFR § 76.611). The drone 18 may be equipped with signal leakage detection equipment that can measure the amplitude 30 of the signal 26 at a distance, such as 3 meters from the cable system component 28, then the computing system 10 can determine that the measured amplitude 30 of the signal 26 emitting from the cable system component 28 exceeds the predetermined threshold 32 and thus that the cable system component 28 is the source of signal leakage. For example, the drone 18 may include signal leakage detection equipment with a dipole antenna that can measure the greatest amplitude of the signal 26 when the antenna is oriented such that the antenna is perpendicular to a line pointing from the drone 18 (e.g., the antenna) to the cable system component 28 (i.e., the source of the leak). The drone 18 can be equipped with a plurality of sensors for identifying and measuring distances, and when the computing system 10 causes the drone 18 to move to the one or more locations that are in proximity to the cable system component 28 of the above-ground cabling infrastructure 24 such that the signal 26 can be detected, a distance 34 between the drone 18 and the cable system component 28 can be measured using the plurality of sensors. The distance 34 can be used to determine that the drone 18 is at a distance where the drone 18 can monitor the signal 26 emitting from the cable system component 28, such as a distance of 3 meters between the drone 18 and the cable system component 28.

In some implementations, the computing system 10 may determine that the cable system component 28 of the above-ground cabling infrastructure 24 is a source of the signal 26 leakage based on a method of attempting to broadcast a signal outside of an area where there is a potential signal leak to cause ingress into the area where there is the potential signal leak. If the area where there is a potential signal leak is the cable system component 28 and the purposeful signal enters the cable system component 28, then the computing system 10 can determine that the cable system component 28 is the source of the signal 26 leakage.

After determining that the source of the signal leakage is the cable system component 28, the computing system 10 can send a notification 36 to the destination device 20. The notification 36 can include an image 38 of the cable system component 28, a location 40 of the cable system component 28 (e.g., latitude and longitude coordinates), a signal indicator 42 of the cable system component 28 (e.g., the amplitude 30 of the signal 26), or a combination of the image 38, the location 40, and the signal indicator 42, as non-limiting examples. In order to include the image 38 of the cable system component 28 in the notification 36, the drone 18 can be equipped with one or more cameras, use the cameras to take pictures of the cable system component 28, and send the images to the computing system 10 for use in the notification 36 and/or for storage in the database 22. The images (e.g., the image 38) can be captured by configuring the one or more cameras of the drone 18 to point in the direction of the cable system component 28 at a time when the drone's signal leakage detection equipment has a dipole antenna oriented such that the antenna is perpendicular to a line pointing from the drone 18 (e.g., the antenna) to the cable system component 28 (i.e., the source of the leak), which can measure the greatest amplitude of the signal 26. For instance, the camera lens of the drone 18 can be perpendicular to the antenna oriented such that the antenna is perpendicular to a line pointing from the drone 18 (e.g., the antenna) to the cable system component 28 (i.e., the source of the signal leak). Providing the notification 36 to the destination device 20 allows a technician using the destination device 20 on the ground to know the source of the signal leakage and quickly fix the leak, which requires only one trip up to the above-ground cabling infrastructure 24 to perform the fix instead of multiple trips to first determine the source of the signal leakage.

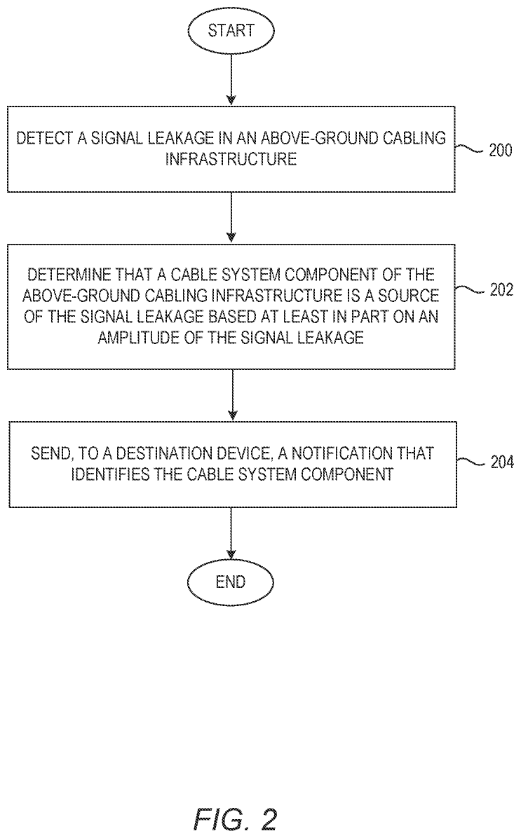

FIG. 2 is a flowchart illustrating operations performed by the computing system of FIG. 1 for CATV system signal leakage detection using drones, according to one example. Elements of FIG. 1 are referenced in describing FIG. 2 for the sake of clarity. In FIG. 2, operations begin with a processor device of a computing device of the computing system 10, such as the processor device 16 of the computing device 12 of FIG. 1, the processor device 16 to detect a signal leakage in an above-ground cabling infrastructure (block 200). The processor device 16 is further to determine that a cable system component of the above-ground cabling infrastructure is a source of the signal leakage based at least in part on an amplitude of the signal leakage (block 202). The processor device 16 is further to send, to a destination device, a notification that identifies the cable system component (block 204).

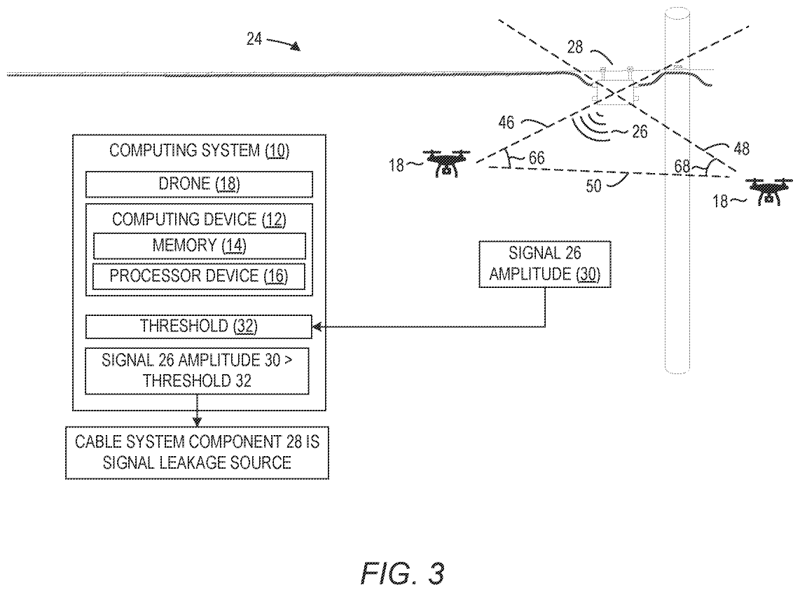

FIG. 3 is a block diagram of the computing system of FIG. 1 for CATV system signal leakage detection using drones, according to one example. Elements of FIG. 1 are referenced in describing FIG. 3 for the sake of clarity. In the example of FIG. 3, the computing system 10 may determine that the source of the signal leakage is the cable system component 28 of the above-ground cabling infrastructure 24 by performing triangulation. Performing triangulation can include causing the drone 18 to identify peaks in the amplitude 30 of the signal 26 above the threshold 32, move to a first location proximate to the signal 26, and move to a second location proximate to the signal 26 such that the angle between the first location and the second location is less than 180° (i.e., a first distance 46 between the drone 18 and the signal 26, a second distance 48 between the drone 18 and the signal 26, and a third distance 50 between the two locations of the drone 18 form a triangle). In some examples, a proximity algorithm may be used by the drone 18 to identify the first location proximate to the signal 26 and the second location proximate to the signal 26, such as by instructing the drone 18 to move to a first location two feet from the signal 26 and move laterally six feet to the second location which is also two feet from the signal. In other examples, a technician may control the drone 18 through the destination device 20 or another computing device, such as a tablet computer, laptop, or mobile phone, to move the drone 18 to the first location proximate to the signal 26 and the second location proximate to the signal 26, such as after the technician received a notification on the device indicating that the signal 26 is leaking from a particular area.

In the triangulation method, the angles between the signal 26 and the two locations that the drone 18 moved to (e.g., angle 66 and angle 68) can be measured to determine the location of the component that is leaking the signal 26. For instance, the two locations the drone 18 moved to can be determined based on geolocation data in order to act as points of the triangle, the angles can be measured based on the geolocation data, and a formula can be used by the computing system 10 to determine the location of the component that is leaking the signal 26 based on the angle measurements. Based on the triangulation and the amplitude 30 of the signal 26, the computing system 10 can determine that the source of the signal 26 that is leaking is the cable system component 28 where the signal 26 was triangulated (i.e., where the first distance 46 between the drone 18 and the signal 26 and the second distance 48 between the drone 18 and the signal 26 intersect).

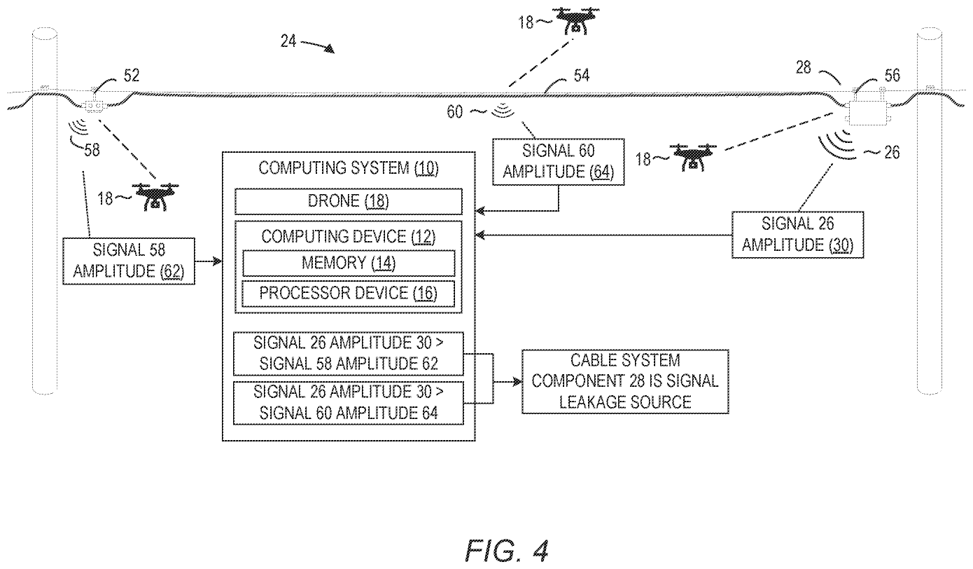

FIG. 4 is a block diagram of the computing system of FIG. 1 for CATV system signal leakage detection using drones, according to one example. Elements of FIG. 1 are referenced in describing FIG. 4 for the sake of clarity. In the example of FIG. 4, the computing system 10 may determine that the source of the signal leakage is the cable system component 28 of the above-ground cabling infrastructure 24 by causing the drone 18 to inspect multiple cable system components of the above-ground cabling infrastructure 24 to identify which of the cable system components is the source of the signal leakage based on the amplitudes of signals emitting from the cable system components. For example, the cable system components of the above-ground cabling infrastructure 24 may include a coaxial cable tap 52, a coaxial cable 54, and a cable signal amplifier 56, and the drone 18 can move to locations in proximity to the coaxial cable tap 52, the coaxial cable 54, and the cable signal amplifier 56. As the drone 18 moves to locations in proximity to these cable system components, the drone 18 can identify the signals emitting from the cable system components, such as signal 58 emitting from the coaxial cable tap 52, signal 60 emitting from the coaxial cable 54, and the signal 26 emitting from the cable signal amplifier 56 based on identifiers such as tags. As the drone 18 identifies the signals, the drone 18 can determine the amplitude of each signal using on-board signal leakage detection equipment, such as an amplitude 62 of the signal 58, an amplitude 64 of the signal 60, and the amplitude 30 of signal 26. For instance, the computing system 10 can determine the amplitudes 62, 64, and 30 of the signals 58, 60, and 26 by causing the drone 18 to move to a location proximate to each of the cable system components of the above-ground cabling infrastructure 24 (e.g., the coaxial cable tap 52, the coaxial cable 54, and the cable signal amplifier 56) and determining the amplitudes 62, 64, and 30 of the signals 58, 60, and 26 emitting from the cable system components (e.g., with the on-board signal leakage detection). The drone 18 may move to the locations proximate to each of the cable system components based on a proximity algorithm that instructs the drone 18 to move to a distance (e.g., two feet) from the cable system component that is emitting the signal. For example, the drone 18 may include signal leakage detection equipment with a dipole antenna that can measure the greatest amplitude of the signals 58, 60, and 26 when the antenna is oriented such that the antenna is perpendicular to a line pointing from the drone 18 (e.g., the antenna) to the coaxial cable tap 52, the coaxial cable 54, and the cable signal amplifier 56 (i.e., the potential sources of the signal leak), and the drone 18 may move to locations such that the greatest amplitude of the signal can be detected.

In order to determine the cable system component that is the source of the signal leakage, the computing system 10 can compare the amplitudes 62, 64, and 30 of the signals 58, 60, and 26, to determine which amplitude is the highest and is thus the source of the signal leakage. In some implementations, the computing system 10 can perform a triangulation of each cable system component by moving the drone 18 to two locations proximate to each cable system component such that the angle between the first location and the second location is less than 180° (i.e., a first distance between the drone 18 and the signal, a second distance between the drone 18 and the signal, and a third distance between the two locations of the drone 18 form a triangle) based on the locations of the signals detected. In some examples, a proximity algorithm may be used by the drone 18 to identify a first location proximate to a cable system component and a second location proximate to the cable system component, such as by instructing the drone 18 to move to a first location two feet from the cable system component and move laterally six feet to the second location which is also two feet from the cable system component. Based on the triangulation and the amplitudes of each signal, the computing system 10 can determine that the source of the signal that is leaking is the cable system component where the signal was triangulated (i.e., where the first distance between the drone 18 and the signal and the second distance between the drone 18 and the signal intersect) and the amplitude is highest. In some examples, the amplitudes of each of the signals emitting from each of the cable system components can be compared to the threshold 32, such as the 108-137 MHz and 225-400 MHZ frequency bands for cable TV transmissions where RF signal leakage (i.e., egress) can be no more than 20 μV/m (i.e., the amplitude 30), to determine whether more than one of the cable system components has a signal that is leaking when measured at 3 meters from the cable system component (47 CFR § 76.610, 47 CFR § 76.611).

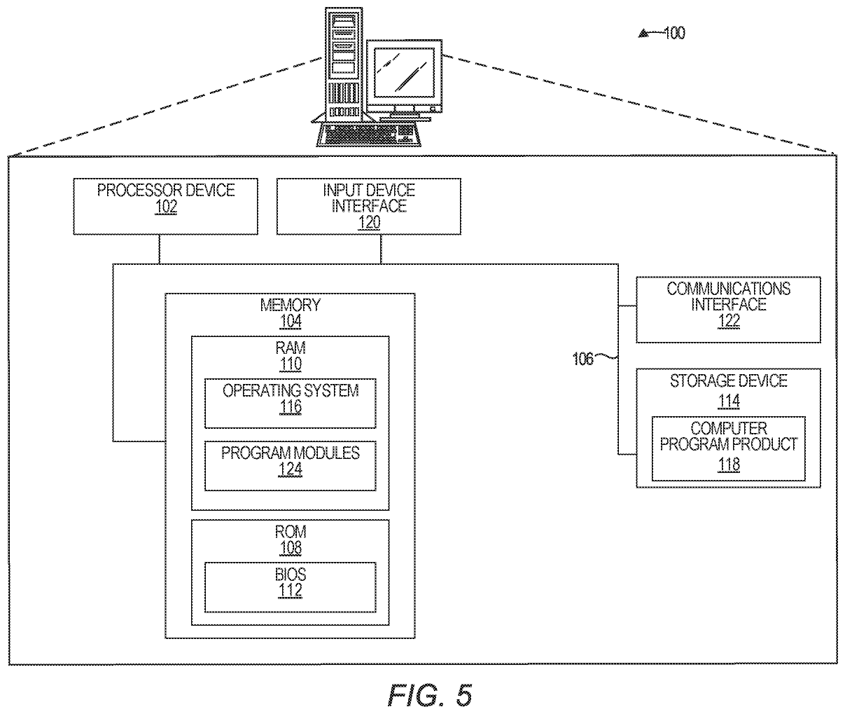

FIG. 5 is a block diagram of a computing device 100, such as the computing device 12 of FIG. 1, suitable for implementing examples according to one example. The computing device 100 may comprise any computing or electronic device capable of including firmware, hardware, and/or executing software instructions to implement the functionality described herein. The computing device 100 includes a processor device 102, such as the processor device 16, a system memory 104, such as the system memory 14, and a system bus 106. The system bus 106 provides an interface for system components including, but not limited to, the system memory 104 and the processor device 102. The processor device 102 can be any commercially available or proprietary processor.

The system bus 106 may be any of several types of bus structures that may further interconnect to a memory bus (with or without a memory controller), a peripheral bus, and/or a local bus using any of a variety of commercially available bus architectures. The system memory 104 may include non-volatile memory 108 (e.g., read-only memory (ROM), erasable programmable read-only memory (EPROM), electrically erasable programmable read-only memory (EEPROM), etc.), and volatile memory 110 (e.g., random-access memory (RAM)). A basic input/output system (BIOS) 112 may be stored in the non-volatile memory 108 and can include the basic routines that help to transfer information between elements within the computing device 100. The volatile memory 110 may also include a high-speed RAM, such as static RAM, for caching data.

The computing device 100 may further include or be coupled to a non-transitory computer-readable storage medium such as a storage device 114, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 114 and other drives associated with computer-readable media and computer-usable media may provide non-volatile storage of data, data structures, computer-executable instructions, and the like.

A number of modules can be stored in the storage device 114 and in the volatile memory 110, including an operating system 116 and one or more program modules 124, which may implement the functionality described herein in whole or in part. All or a portion of the examples may be implemented as a computer program product 118 stored on a transitory or non-transitory computer-usable or computer-readable storage medium, such as the storage device 114, which includes complex programming instructions, such as complex computer-readable program code, to cause the processor device 102 to carry out the steps described herein. Thus, the computer-readable program code can comprise software instructions for implementing the functionality of the examples described herein when executed on the processor device 102. The processor device 102 may serve as a controller, or control system, for the computing device 100 that is to implement the functionality described herein.

An operator, such as a user, may also be able to enter one or more configuration commands through a keyboard (not illustrated), a pointing device such as a mouse (not illustrated), or a touch-sensitive surface such as a display device (not illustrated). Such input devices may be connected to the processor device 102 through an input device interface 120 that is coupled to the system bus 106 but can be connected by other interfaces such as a parallel port, an Institute of Electrical and Electronic Engineers (IEEE) 1394 serial port, a Universal Serial Bus (USB) port, an IR interface, and the like. The computing device 100 may also include a communications interface 122 suitable for communicating with the network as appropriate or desired. The computing device 100 may also include a video port (not illustrated) configured to interface with the display device (not illustrated), to provide information to the user.

Individuals will recognize improvements and modifications to the preferred examples of the disclosure. All such improvements and modifications are considered within the scope of the concepts disclosed herein and the claims that follow.

What is claimed is:

1. A method, comprising:
detecting, by a computing system comprising a drone, a signal leakage in an above-ground cabling infrastructure;
determining, by the computing system, that a cable system component of the above-ground cabling infrastructure is a source of the signal leakage based at least in part on an amplitude of the signal leakage; and
sending, by the computing system to a destination device, a notification that identifies the cable system component.

2. The method of claim 1, wherein detecting the signal leakage in the above-ground cabling infrastructure comprises identifying a signal produced by the above-ground cabling infrastructure, wherein the signal matches a predetermined type of signal.

3. The method of claim 1, wherein determining that the cable system component of the above-ground cabling infrastructure is the source of the signal leakage comprises:
performing a triangulation of the cable system component, wherein an amplitude of a signal emitting from the cable system component exceeds a predetermined threshold; and
determining, based on the triangulation and the amplitude of the signal emitting from the cable system component, that the cable system component is the source of the signal leakage.

4. The method of claim 1, wherein determining that the cable system component of the above-ground cabling infrastructure is the source of the signal leakage comprises:
causing the drone to move to one or more locations in proximity to the cable system component;
monitoring, by the drone, a signal emitting from the cable system component; and
determining that an amplitude of the signal exceeds a predetermined threshold.

5. The method of claim 4, wherein the drone includes a plurality of sensors and wherein causing the drone to move to the one or more locations in proximity to the cable system component comprises:
determining, based on the plurality of sensors, a distance between the drone and the cable system component; and
determining that the distance between the drone and the cable system component is a length where the drone can monitor the signal emitting from the cable system component.

6. The method of claim 1, wherein determining that the cable system component of the above-ground cabling infrastructure is the source of the signal leakage comprises:
causing the drone to move in proximity to a plurality of cable system components;
identifying a plurality of signals emitting from the plurality of cable system components;
determining an amplitude of each signal of the plurality of signals; and
determining that a signal from among the plurality of signals has a highest amplitude, wherein the signal from the plurality of signals emits from the cable system component.

7. The method of claim 6, wherein determining the amplitude of each signal of the plurality of signals comprises:
causing the drone to move to a location proximate to each of the plurality of cable system components; and
determining an amplitude of a signal emitting from each cable system component.

8. The method of claim 1, further comprising:
prior to detecting the signal leakage in the above-ground cabling infrastructure, obtaining geolocation data corresponding to a location of the above-ground cabling infrastructure; and
causing the drone to move to a location proximate to the above-ground cabling infrastructure based on the geolocation data.

9. The method of claim 1, further comprising:
subsequent to determining that the cable system component of the above-ground cabling infrastructure is the source of the signal leakage, causing the drone to capture at least one image of the cable system component; and
storing the at least one image in a database.

10. The method of claim 1, wherein the signal leakage comprises a radio frequency (RF) signal leakage.

11. The method of claim 1, wherein the cable system component comprises one or more of a cable signal amplifier, a coaxial cable tap, or a coaxial cable.

12. The method of claim 1, wherein the destination device comprises a display device configured to control the drone.

13. The method of claim 1, wherein the notification comprises one or more of an image of the cable system component, a location of the cable system component, or a signal indicator of the cable system component.

14. A computing device, comprising:
a memory; and
a processor device coupled to the memory, the processor device to:
detect a signal leakage in an above-ground cabling infrastructure;
determine that a cable system component of the above-ground cabling infrastructure is a source of the signal leakage based at least in part on an amplitude of the signal leakage; and
send, to a destination device, a notification that identifies the cable system component.

15. The computing device of claim 14, wherein to detect the signal leakage in the above-ground cabling infrastructure, the processor device is further to identify a signal produced by the above-ground cabling infrastructure, wherein the signal matches a predetermined type of signal.

16. The computing device of claim 14, wherein to determine that the cable system component of the above-ground cabling infrastructure is the source of the signal leakage, the processor device is further to:
perform a triangulation of the cable system component, wherein an amplitude of a signal emitting from the cable system component exceeds a predetermined threshold; and
determine, based on the triangulation and the amplitude of the signal emitting from the cable system component, that the cable system component is the source of the signal leakage.

17. The computing device of claim 14, wherein to determine that the cable system component of the above-ground cabling infrastructure is the source of the signal leakage, the processor device is further to:
cause a drone to move to one or more locations in proximity to the cable system component;
monitor, by the drone, a signal emitting from the cable system component; and
determine that an amplitude of the signal exceeds a predetermined threshold.

18. The computing device of claim 14, wherein to determine that the cable system component of the above-ground cabling infrastructure is the source of the signal leakage, the processor device is further to:
cause a drone to move in proximity to a plurality of cable system components;
identify a plurality of signals emitting from the plurality of cable system components;
determine an amplitude of each signal of the plurality of signals; and
determine that a signal from among the plurality of signals has a highest amplitude, wherein the signal from the plurality of signals emits from the cable system component.

19. The computing device of claim 14, wherein the processor device is further to:
prior to detecting the signal leakage in the above-ground cabling infrastructure, obtain geolocation data corresponding to a location of the above-ground cabling infrastructure; and
cause a drone to move to a location proximate to the above-ground cabling infrastructure based on the geolocation data.

20. A non-transitory computer-readable storage medium that includes computer-executable instructions that, when executed, cause one or more processor devices to:
detect a signal leakage in an above-ground cabling infrastructure;
determine that a cable system component of the above-ground cabling infrastructure is a source of the signal leakage based at least in part on an amplitude of the signal leakage; and
send, to a destination device, a notification that identifies the cable system component.
